(19) United States
(12) Patent Application Publication
(10) Pub. No.: US 2026/0218379 A1
(43) Pub. Date: Jul. 30, 2026

(54) EXHAUST GAS PRETREATMENT EQUIPMENT FOR SEMICONDUCTOR MANUFACTURING FACILITY

(71) Applicant: LOT CES CO., LTD., Osan-si, Gyeonggi-do (KR)

(72) Inventors: Jin Ho BAE, Hwaseong-si, Gyeonggi-do (KR); Tae Hyung LEE, Hwaseong-si, Gyeonggi-do (KR); Do Won KIM, Pyeongtaek-si, Gyeonggi-do (KR)

(73) Assignee: LOT CES CO., LTD., Osan-si, Gyeonggi-do (KR)

(21) Appl. No.: 19/146,911

(22) PCT Filed: Apr. 17, 2024
(86) PCT No.: PCT/KR2024/005106

§ 371 Date: Jul. 9, 2025

(30) Foreign Application Priority Data
Jun. 12, 2023 (KR) 10-2023-0075041

(51) Int. Cl. C23C 16/44; C23C 16/455; H10P 72/00

(52) U.S. Cl. CPC C23C 16/4412; C23C 16/45536; H10P 72/0402

(57) ABSTRACT

Provided is exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment including: an exhaust gas reaction chamber installed on the chamber exhaust pipe; and a plasma reactor generating a plasma gas including reactive species generated by decomposing a source gas by generating plasma, wherein the exhaust gas reaction chamber includes an exhaust gas reaction unit having an exhaust gas reaction space in which ingredients to be treated included in the exhaust gas and the reactive species are mixed with each other and react with each other, therein, and a cooling unit installed on the exhaust gas reaction unit.

### TECHNICAL FIELD

The present invention relates to semiconductor manufacturing equipment technology, and more particularly, to technology for preventing deterioration of fluidity of an exhaust gas discharged from a process chamber of a semiconductor manufacturing facility.

### BACKGROUND ART

Semiconductor devices have been manufactured by repeatedly performing processes such as photolithography, etching, diffusion and metal deposition, and the like on a wafer in a semiconductor process chamber by using various process gases. After the processes are completed in the semiconductor process chamber, a residual gas is present in the semiconductor process chamber, and since the residual gas in the process chamber contains toxic ingredients, the residual gas is discharged by a vacuum pump and is purified by exhaust gas treatment equipment such as a scrubber.

A low-fluorine tungsten (LFW) process is a process in which atomic layer deposition (ALD) is performed using a process gas including tungsten hexafluoride (WF₆), diborane (B₂H₆), argon (Ar) and hydrogen (H₂) in a semiconductor process. After the LFW process is performed, an exhaust gas including WF₆ and B₂H₆ is discharged from the semiconductor process chamber by the vacuum pump. WF₆ and B₂H₆ contained in the exhaust gas in the LFW process react with each other so that a membranous Wx by-product can be generated. The membranous Wx by-product is deposited on the vacuum pump and deteriorates the performance of the vacuum pump and causes a reduction in a mean time between failure (MTBF) of the vacuum pump.

An amorphous carbon layer (ACL) process is a process in which an ACL is deposited and formed in the semiconductor process. After the ACL process is performed, a residual gas including hydrogenated amorphous carbon (a-C:H) is generated in the process chamber. After the ACL process is performed, an exhaust gas including a-C:H is discharged from the semiconductor process chamber by the vacuum pump. a-C:H contained in the exhaust gas in the ACL process is deposited on the vacuum pump, deteriorates the performance of the vacuum pump and causes a reduction in the MTBF of the vacuum pump.

A tetraethyl ortho silicate (Si(OC₂H₅)₄) (TEOS) process is a process in which a TEOS layer is deposited on a wafer using a TEOS gas in the semiconductor process. After the TEOS process is performed, a residual gas including TEOS is generated in the process chamber. After the TEOS process is performed, an exhaust gas including TEOS is discharged from the semiconductor process chamber by the vacuum pump. TEOS contained in the exhaust gas reacts with oxygen and generates a silicon dioxide (SiO₂) powder as a by-product, and the SiO₂ powder is deposited on the vacuum pump, deteriorates the performance of the vacuum pump and causes a reduction in the MTBF of the vacuum pump.

In relation to the present invention, Korean Patent Registration No. 10-1315880 discloses a configuration in which a LFW process is performed in the manufacture of a metal wiring structure, and Korean Patent Laid-open Publication No. 10-2009-0057487 discloses a configuration in which an ACL process is performed in the manufacture of a semiconductor device, and Korean Patent Laid-open Publication No. 10-2009-0070800 discloses a configuration in which a TEOS process is performed in the manufacture of a semiconductor device, and Korean Patent Laid-open Publication No. 10-2019-0019651 discloses a configuration of a plasma chamber for processing an exhaust gas.

### DETAILED DESCRIPTION OF THE INVENTION

### Technical Problem

The present invention provides exhaust gas pretreatment equipment for pretreating an exhaust gas so as to prevent deterioration of fluidity of the exhaust gas discharged from a process chamber in which a semiconductor manufacturing process using various process gases is performed in a semiconductor manufacturing facility.

The present invention also provides exhaust gas pretreatment equipment for pretreating an exhaust gas before the exhaust gas is introduced into a vacuum pump so as to prevent a membranous Wx by-product from being deposited on the vacuum pump for discharging a residual gas from a semiconductor process chamber.

The present invention also provides exhaust gas pretreatment equipment for pretreating an exhaust gas before the exhaust gas is introduced into a vacuum pump so as to prevent hydrogenated amorphous carbon (a-C:H) from being deposited on the vacuum pump for discharging a residual gas from a semiconductor process chamber.

The present invention also provides exhaust gas pretreatment equipment for pretreating an exhaust gas before the exhaust gas is introduced into a vacuum pump so as to prevent a silicon dioxide (SiO₂) powder from being deposited on the vacuum pump for discharging a residual gas from a semiconductor process chamber.

### Technical Solution

According to an aspect of the present invention, there is provided exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment including: an exhaust gas reaction chamber installed on the chamber exhaust pipe; and a plasma reactor generating a plasma gas including reactive species generated by decomposing a source gas by generating plasma, wherein the exhaust gas reaction chamber includes an exhaust gas reaction unit having an exhaust gas reaction space in which ingredients to be treated included in the exhaust gas and the reactive species are mixed with each other and react with each other, therein, and a cooling unit installed on the exhaust gas reaction unit.

According to another aspect of the present invention, there is provided exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment including: an exhaust gas reaction chamber installed on the chamber exhaust pipe; a plasma reactor generating a plasma gas including reactive species generated by decomposing a source gas by generating plasma; and a plasma supply pipe connecting the exhaust gas reaction chamber and the plasma reactor to each other, wherein the plasma supply pipe includes a plasma supply passage on which the plasma gas generated by the plasma reactor is discharged and flows, and a cooling fluid passage on which a cooling fluid flows, and the exhaust gas reaction chamber includes an exhaust gas reaction unit having an exhaust gas reaction space in which ingredients to be treated included in the exhaust gas and the reactive species introduced through the plasma supply passage are mixed with each other and react with each other, therein.

### Effects of the Invention

According to the present invention, all of the objectives of the present invention described above can be achieved. Specifically, according to exhaust gas pretreatment equipment according to the present invention, an exhaust gas reaction chamber is installed on a chamber exhaust pipe on which an exhaust gas flows, and reactive species generated in an external plasma reactor are supplied to the exhaust gas reaction chamber, and ingredients for causing powder formation contained in the exhaust gas react with the reactive species in the exhaust gas reaction chamber and are removed so that deterioration of fluidity of the exhaust gas can be effectively prevented.

In addition, the exhaust gas reaction chamber is cooled by a cooling unit so that damage of the exhaust gas pretreatment equipment by overheat can be prevented.

Furthermore, diborane (B₂H₆) contained in the exhaust gas discharged from the semiconductor process chamber reacts with reactive species (F*) generated by decomposing nitrogen trifluoride (NF₃) by the external plasma reactor in the exhaust gas process chamber and is removed so that generation of the Wx by-product is suppressed and deterioration of the performance of the vacuum pump can be prevented.

Moreover, a silicon dioxide (SiO₂) powder contained in the exhaust gas discharged from the semiconductor process chamber reacts with reactive species (F*) generated by decomposing NF₃ by the external plasma reactor in the exhaust gas process chamber and is removed so that deposition of the SiO₂ powder on the vacuum pump can be prevented.

In addition, hydrogenated amorphous carbon (a-C:H) contained in the exhaust gas discharged from the semiconductor process chamber reacts with reactive species (F*) generated by decomposing oxygen (O₂) by the external plasma reactor in the exhaust gas process chamber and is removed so that deposition of a-C:H on the vacuum pump can be prevented.

### BRIEF DESCRIPTION OF THE DRAWINGS

FIG. 1 is a diagram illustrating a schematic configuration of a semiconductor manufacturing facility in which exhaust gas pretreatment equipment according to an embodiment of the present invention is installed;

FIG. 2 is a longitudinal cross-sectional view of a plasma reactor in pretreatment equipment of the semiconductor manufacturing facility shown in FIG. 1;

FIG. 3 is a perspective view of a magnetic core shown in FIG. 2;

FIG. 4 is a diagram specifically illustrating the configuration of a portion ‘E’ in FIG. 1;

FIG. 5 is a perspective view of an exhaust gas reaction chamber of configurations of FIG. 4;

FIG. 6 is a cross-sectional view of the exhaust gas reaction chamber taken along a line A-A′ of FIG. 5;

FIG. 7 is a cross-sectional view of the exhaust gas reaction chamber taken along a line B-B′ of FIG. 5;

FIG. 8 is a perspective view illustrating a plasma supply pipe of the configurations of FIG. 4; and

FIGS. 9, 10, and 11 are diagrams schematically illustrating a state in which pretreatment is performed on an exhaust gas in the exhaust gas reaction chamber of FIG. 4.

### BEST MODE FOR CARRYING OUT THE INVENTION

Hereinafter, the configuration and operation of the present invention will be described in detail with reference to the accompanying drawings.

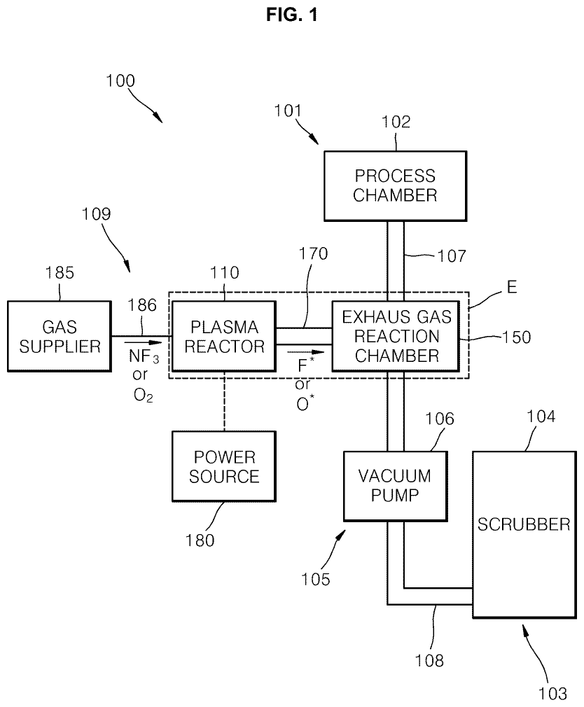

FIG. 1 is a block diagram illustrating a schematic configuration of a semiconductor manufacturing facility in which exhaust gas pretreatment equipment according to an embodiment of the present invention is installed. Referring to FIG. 1, a semiconductor manufacturing facility 100 includes semiconductor manufacturing equipment 101 in which a semiconductor manufacturing process for manufacturing a semiconductor device is performed, exhaust gas treatment equipment 103 for treating gas discharged from the semiconductor manufacturing equipment 101, exhaust equipment 105 for discharging gas from the semiconductor manufacturing equipment 101 to allow the gas to flow into the exhaust gas treatment equipment 103, and exhaust gas pretreatment equipment 109 according to an embodiment of the present invention that prevents deterioration of fluidity of the gas by pretreating gas discharged from the semiconductor manufacturing equipment 101.

The semiconductor manufacturing equipment 101 manufactures a semiconductor device by performing a semiconductor manufacturing process using various process gases. The semiconductor manufacturing equipment 101 includes a semiconductor process chamber 102 in which the semiconductor manufacturing process using various process gases is performed. Although not shown, the semiconductor manufacturing equipment 101 further includes a process gas supply unit for supplying various types of process gases required for the semiconductor process chamber 102.

The semiconductor process chamber 102 includes all types of semiconductor process chambers that are generally used to manufacture the semiconductor device in a technical field of a semiconductor manufacturing facility. A residual gas generated in the semiconductor process chamber 102 is discharged by the exhaust equipment 105 to the outside and is purified by the exhaust gas treatment equipment 103. In the present embodiment, a semiconductor process to be performed in the semiconductor process chamber 102 will be described as a low-fluorine tungsten (LFW) process in which atomic layer deposition (ALD) is performed using a process gas including tungsten hexafluoride (WF₆), diborane (B₂H₆), argon (Ar) and hydrogen (H₂), or an amorphous carbon layer (ACL) process in which amorphous carbon is deposited by a process gas including propene (C3H6), Ar and helium (He) so that an ACL is formed, or a tetraethyl ortho silicate (Si(OC₂H₅)₄) (TEOS) process in which a TEOS layer is deposited on a wafer using a TEOS gas.

The LFW process may be a process in which a metal wiring structure is formed in a semiconductor memory device, for example, as disclosed in Korean Patent Registration No. 10-1315880. The residual gas generated after the semiconductor process is performed in the semiconductor process chamber 102, is discharged as an exhaust gas from the process chamber 102 using the exhaust equipment 105. The exhaust gas discharged from the semiconductor process chamber 102 may include WF₆ and B₂H₆. WF₆ and B₂H₆ contained in the exhaust gas discharged from the semiconductor process chamber 102 react with each other so that a membranous Wx by-product can be generated, and the membranous Wx by-product is deposited on the exhaust equipment 105 and causes deterioration of the performance of the exhaust equipment 105. According to the present invention, B₂H₆ is removed by the exhaust gas pretreatment equipment 109, and generation of the membranous Wx by-product is suppressed.

The ACL process may be a semiconductor process disclosed in Korean Patent Laid-open Publication No. 10-2009-0057487, for example. After the ACL process is performed, a residual gas including a-C:H is generated in the process chamber 102. After the ACL process is performed, the residual gas including hydrogenated amorphous carbon (a-C:H) generated in the semiconductor process chamber 102 is discharged as an exhaust gas from the semiconductor process chamber 102 by the exhaust equipment 105. a-C:H contained in the exhaust gas discharged from the semiconductor process chamber 102 is deposited on the exhaust equipment 105 and deteriorates the performance of the exhaust equipment 105. According to the present invention, a-C:H is removed by the exhaust gas pretreatment equipment 109, and deposition of a-C:H is prevented.

The TEOS process may be a semiconductor process disclosed in Korean Patent Laid-open Publication No. 10-2009-0070800, for example. After the TEOS process is performed, a residual gas including TEOS is generated in the process chamber. After the TEOS process is performed, the exhaust gas including TEOS is discharged from the semiconductor process chamber by the vacuum pump. TEOS contained in the exhaust gas reacts with oxygen and generates a SiO₂ powder, and the SiO₂ powder is deposited on the exhaust equipment 105 and deteriorates the performance of the exhaust equipment 105. According to the present invention, the SiO₂ powder is removed by the exhaust gas pretreatment equipment 109, and deposition of the SiO₂ powder is prevented.

The exhaust gas treatment equipment 103 treats and purifies harmful ingredients contained in the exhaust gas discharged from the semiconductor process chamber 102 by the exhaust equipment 105. The exhaust gas treatment equipment 103 includes a scrubber 104 for treating the exhaust gas. The scrubber 104 includes all types of scrubbers generally used to treat the exhaust gas in the technical field of a semiconductor manufacturing facility.

The exhaust equipment 105 discharges the residual gas generated in the semiconductor process chamber 102 after the process from the semiconductor process chamber 102. The exhaust equipment 105 includes a vacuum pump 106, a chamber exhaust pipe 107 connecting the semiconductor process chamber 102 to the vacuum pump 106, and a pump exhaust pipe 108 extending from the vacuum pump 106 downstream.

The vacuum pump 106 forms a negative pressure in the semiconductor process chamber 102 through the chamber exhaust pipe 107 that connects the semiconductor process chamber 102 to the vacuum pump 106, so as to discharge the residual gas in the semiconductor process chamber 102 from the semiconductor process chamber 102. The vacuum pump 106 includes the configuration of a vacuum pump that is generally used to discharge gas in the technical field of the semiconductor manufacturing facility and thus, here, detailed descriptions thereof will be omitted. A membranous Wx by-product generated as a by-product of the LFW process, a-C:H generated as a by-product of the ACL process, and a SiO₂ powder generated as a by-product of the TEOS process may be deposited on the vacuum pump 106 so that the performance of the vacuum pump 106 may be reduced.

According to the present invention, generation of the membranous Wx by-product is suppressed by the exhaust gas pretreatment equipment 109, and a-C:H and the SiO₂ powder are removed so that a mean time between failure (MTBF) of the vacuum pump 106 is extended.

The chamber exhaust pipe 107 connects an exhaust of the semiconductor process chamber 102 to an intake of the vacuum pump 106 between the semiconductor process chamber 102 and the vacuum pump 106. The residual gas in the semiconductor process chamber 102 is discharged as an exhaust gas through the chamber exhaust pipe 107 by the negative pressure generated by the vacuum pump 106. While the exhaust gas flows through the chamber exhaust pipe 107, the exhaust gas is pretreated by the exhaust gas pretreatment equipment 109.

The pump exhaust pipe 108 extends from the vacuum pump 106 downstream. The pump exhaust pipe 108 is connected to an outlet of the vacuum pump 106 so that the exhaust gas discharged from the vacuum pump 106 flows into the pump exhaust pipe 108. The scrubber 104 is connected to a downstream end of the pump exhaust pipe 108 so that the exhaust gas discharged from the vacuum pump 106 flows into the scrubber 104 through the pump exhaust pipe 108.

The exhaust gas pretreatment equipment 109 pretreats the exhaust gas discharged from the semiconductor process chamber 102 so as to prevent reduction of the fluidity of the exhaust gas discharged from the semiconductor process chamber 102. The exhaust gas pretreatment equipment 109 generates reactive species using plasma, reacts the generated reactive species with ingredients to be treated included in the exhaust gas before the exhaust gas discharged from the semiconductor process chamber 102 flows into the vacuum pump 106, and removes the ingredients to be treated. The exhaust gas pretreatment equipment 109 includes a plasma reactor 110 that generates reactive species using plasma, a power source 180 that supplies power to the plasma reactor 110, a gas supplier 185 that supplies a source gas to the plasma reactor 110, an exhaust gas reaction chamber 150, which is installed on the chamber exhaust pipe 107 and in which the reactive species generated by the plasma reactor 110 react with ingredients to be treated included in the exhaust gas, and a plasma supply pipe 170 that connects the plasma reactor 110 and the exhaust gas reaction chamber 150 to each other.

The plasma reactor 110 generates reactive species by decomposing gas supplied from the gas supplier 185 using plasma. In the present embodiment, the plasma reactor 110 generates excited fluorine atoms (F*), which are reactive fluorine, or excited oxygen atoms (O*), which are reactive oxygen, as reactive species by using plasma. In the present embodiment, it will be described that the exited fluorine atoms (F*) are generated by decomposing nitrogen trifluoride (NF₃) supplied from the gas supplier 190, by plasma in the plasma reactor 110 and the excited oxygen atoms (O*) are generated by decomposing oxygen (O₂) supplied from the gas supplier 185 by plasma in the plasma reactor 110. In the present embodiment, it will be described that the plasma reactor 110 is an inductively coupled plasma (ICP) reactor using ICP. In the present embodiment, although it will be described that the plasma reactor 110 uses ICP, but the present invention is not limited thereto. In the present invention, the plasma reactor includes all types of plasma reactors (for example, a plasma reactor using capacitively coupled plasma (CCP)) that generates a plasma reaction, and this also belongs to the scope of the present invention.

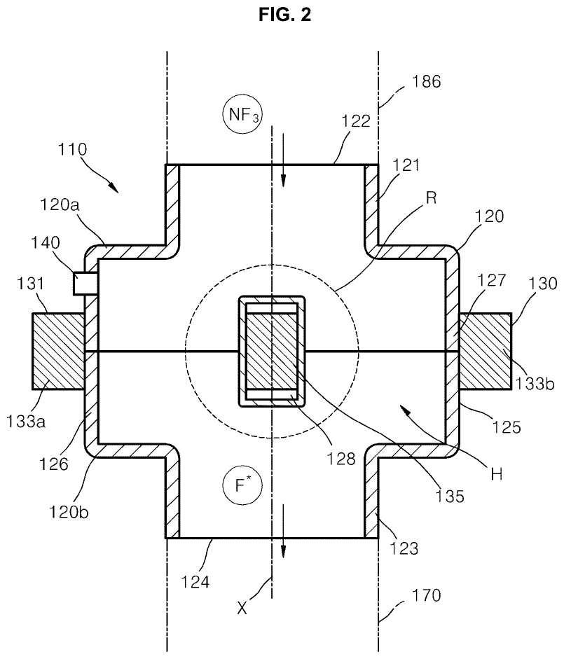

FIG. 2 is a longitudinal cross-sectional view of a schematic configuration of the plasma reactor 110. Referring to FIG. 2, the plasma reactor 110 includes a plasma reaction chamber 120, a magnetic core 130 arranged to surround the plasma reaction chamber 120, an igniter 140 for plasma ignition, and a coil (not shown) wound on the magnetic core 130 and powered from the power source (180 of FIG. 1).

The plasma reaction chamber 120 that is a chamber having a toroidal shape includes a gas inlet 131, a gas outlet 133 located spaced apart from the gas inlet 131, and a plasma reactor 135, which connects the gas inlet 131 to the gas outlet 133 in which a plasma reaction occurs. The plasma reaction chamber 120 generates reactive species by decomposing gas supplied from the gas supplier (185 of FIG. 1) by using plasma.

The gas inlet 121 has a shape of a short pipe that extends around a straight extension axis line X, and a front end of the gas inlet 121 is open so that an inlet 122 through which gas is introduced, may be formed. The inlet 122 communicates with the gas supplier 185 through the gas inlet (186 of FIG. 1). Nitrogen trifluoride (NF₃) or oxygen (O₂) supplied by the gas supplier 185 through the inlet 122 is introduced into the plasma reaction chamber 120.

The gas outlet 123 has a shape of a short pipe located coaxially spaced apart from the gas inlet 121 on the extension axis line X, and a rear end of the gas outlet 123 is open so that an outlet 124 through which gas is discharged, may be formed. The gas outlet 124 communicates with the exhaust gas reaction chamber (150 of FIG. 1) through the plasma supply pipe (170 of FIG. 1). After the reactive species generated by the plasma reaction chamber 120 are discharged through the outlet 124, the reactive species flow along the plasma supply pipe (187 of FIG. 1) and flows into the exhaust gas reaction chamber (150 of FIG. 1).

The plasma reactor 125 connects the spaced gas inlet 121 and the gas outlet 123 to each other to form a plasma reaction area H in which a thermal reaction with respect to gas and a plasma reaction occur. The plasma reactor 125 includes a first connector portion 126 and a second connector portion 127 located spaced apart from each other at both sides of the extension axis line X. The first connector portion 126 and the second connector portion 127 extend parallel to the extension axis line X and communicate with the gas inlet 121 and the gas outlet 123. Thus, plasma is generated in the plasma reactor 125 along a ring-shaped discharge loop R as shown by a dashed line.

Gas introduced through the inlet 122 is decomposed by plasma formed in the plasma reaction area H so that reactive species may be formed. As shown, when nitrogen trifluoride (NF₃) is introduced through the inlet 122, nitrogen trifluoride (NF₃) is decomposed in the plasma reaction area H so that excited fluorine atoms (F*) and fluoride (F₂) that are reactive species may be generated. Specifically, in the plasma reaction area H, nitrogen trifluoride (NF₃) may be decomposed as ingredients including nitrogen (N₂), fluoride (F₂), excited nitrogen atoms (N*), excited fluorine atoms (F*), and electrons (e). Although not shown, when oxygen (O₂) is introduced through the inlet 122, oxygen (O₂) is decomposed in the plasma reaction area H so that the excited oxygen atoms (O*) that are reactive species may be generated.

In the present embodiment, it will be described that the plasma reaction chamber 120 is configured by combining the first chamber member 120a with the second chamber member 120b. The first chamber member 120a includes the entire gas inlet 121, part of the first connector portion 126 and part of the second connector portion 127, which are connected to the gas inlet 121. The second chamber member 120b includes the entire gas outlet 123, and part of the first connector portion 126 and part of the second connector portion 127, which are connected to the gas outlet 123.

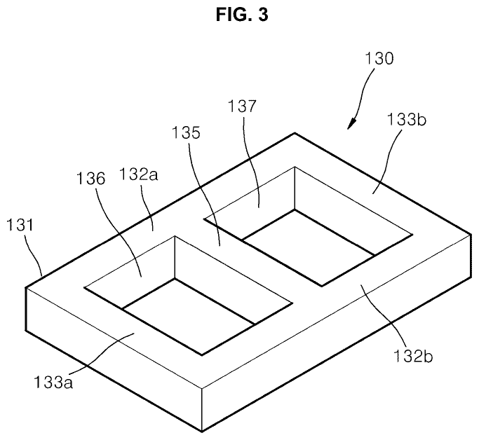

The magnetic core 130 is arranged to surround the plasma reaction chamber 120. In the present embodiment, it will be described that the magnetic core 130 is a ferrite core generally used in the ICP generating device. FIG. 3 is a perspective view of the magnetic core 130. Referring to FIGS. 2 and 3, the magnetic core 130 includes a ring-shaped ring portion 131 surrounding the plasma reactor 125 of the plasma reaction chamber 120 from the outside, and a connector 135 crossing an inner area of the ring portion 131.

The ring portion 131 has a generally rectangular ring shape, is arranged perpendicular to the extension axis line X, and surrounds the plasma reaction unit 125 of the plasma reaction chamber 120 from the outside. The rectangular ring portion 131 includes two opposite long sides 132a and 132b, and two opposite short sides 133a and 133b.

The connector 135 extends in a straight line to connect between two opposite long sides 132a and 132b of the ring portion 131. Both ends of the connector 135 are connected to centers of each of two long sides 132a and 132b. The connector 135 is arranged to pass through an aperture 128 formed between the first connector portion 126 and the second connector portion 127 of the plasma reaction chamber 120. The inner area of the ring portion 131 is divided into a first through hole 136 and a second through hole 137 by the connector 135, and the first connector portion 126 of the plasma reaction chamber 120 passes through the first through hole 136, and the second connector portion 127 of the plasma reaction chamber 120 passes through the second through hole 137. Thus, the magnetic core 130 has a shape surrounding each of the first connector portion 126 and the second connector portion 127 of the plasma reaction chamber 120 from the outside.

Referring to FIG. 2, the igniter 140 ignites plasma by receiving power of a high voltage from the power source (180 of FIG. 1). In the present embodiment, it will be described that the igniter 140 is located adjacent to the gas inlet 121 in a plasma reaction unit 125 of the plasma reaction chamber 120, and the present invention is not limited thereto.

A coil (not shown) is wound on the magnetic core 130 and is connected to the power source (180 of FIG. 1). The coil (not shown) forms an induced magnetic flux in the magnetic core 130 by receiving radio frequency alternating current power through the power source (180 of FIG. 1). An induced magnetic field is generated by the inducted magnetic flux formed in the magnetic core 130, and plasma is formed by the generated induced magnetic field.

Referring to FIG. 1, the power source 180 applies radio frequency alternating current power to the coil (not shown) wound on the magnetic core (130 of FIG. 2) for generation of ICP. Also, the power source 180 supplies power to the igniter (140 of FIG. 1).

The gas supplier 185 stores a source gas of reactive species generated by plasma in the plasma reactor 110 and supplies the stored source gas to the plasma reactor 190 through the gas inlet 186. In the present embodiment, it will be described that the gas supplier 185 supplies nitrogen trifluoride (NF₃) or oxygen (O₂) as a source gas of reactive species to the plasma reactor 110.

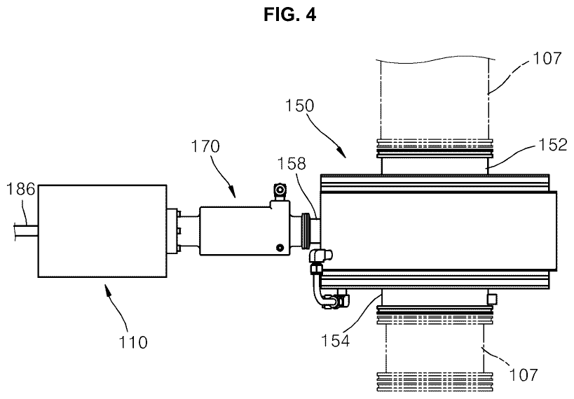

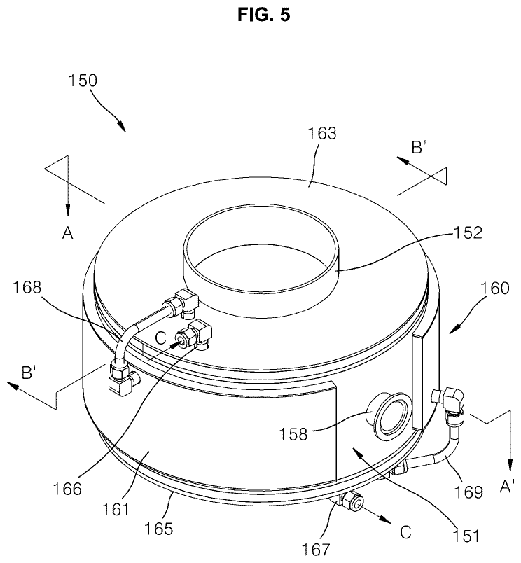

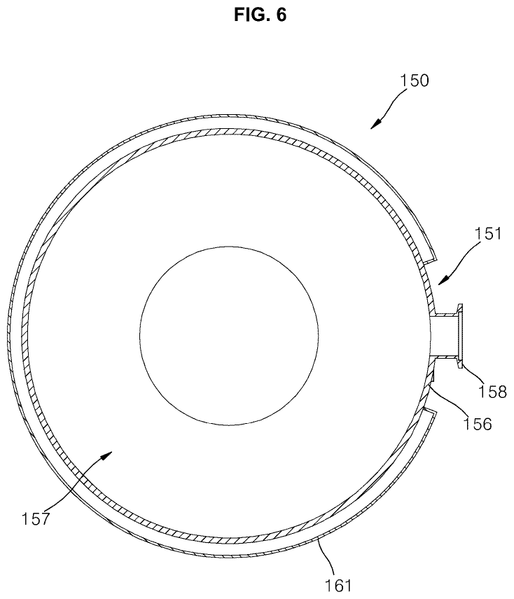

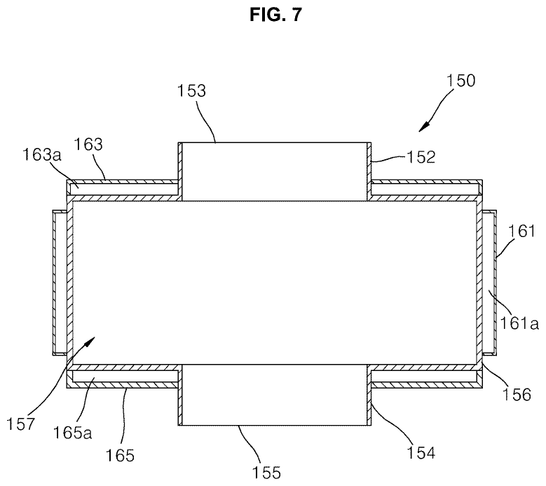

Referring to FIGS. 1 and 4, the exhaust gas reaction chamber 150 is installed on the chamber exhaust pipe 107 and receives the reactive species generated by the plasma reactor 110 through the plasma supply pipe 170. The ingredients to be treated included in the exhaust gas react with the reactive species in the exhaust gas reaction chamber 150 and are removed. Referring to FIGS. 5, 6, and 7, the exhaust gas reaction chamber 150 includes a chamber body 151, and a cooling unit 160 installed on the chamber body 151. In the present invention, the exhaust gas reaction chamber 150 installed on the chamber exhaust pipe 107 includes a case where the exhaust gas reaction chamber 150 is installed at an end of the downstream of the chamber exhaust pipe 107, and in this case, the exhaust gas reaction chamber 150 is located at a tip of the vacuum pump 106.

The chamber body 151 includes an exhaust gas inlet 152, an exhaust gas outlet 154 located spaced apart from the exhaust gas inlet 152, and an exhaust gas reaction unit 156, which connects the exhaust gas inlet 152 and the exhaust gas outlet 154 to each other and in which a reaction of the reactive species and the ingredients to be treated occurs.

The exhaust gas inlet 152 has a shape of a short pipe, and a front end of the exhaust gas inlet 152 is open so that an inlet 153 through which the exhaust gas is introduced, may be formed. The inlet 153 communicates with the semiconductor process chamber (102 of FIG. 1) through the chamber exhaust pipe (107 of FIG. 1). The exhaust gas discharged from the semiconductor process chamber (102 of FIG. 1) through the inlet 153 is introduced into the exhaust gas reaction unit 156.

The exhaust gas outlet 154 has a shape of a short pipe located coaxially spaced apart from the exhaust gas inlet 152, and a rear end of the exhaust gas outlet 154 is open so that an outlet 155 through which gas is discharged, may be formed. The outlet 155 communicates with the vacuum pump (106 of FIG. 1) through the chamber exhaust pipe (107 of FIG. 1). After the gas discharged from the exhaust gas reaction unit 156 through the outlet 155 flows into the vacuum pump (106 of FIG. 1) through the chamber exhaust pipe (107 of FIG. 1).

The exhaust gas reaction unit 156 connects the exhaust gas inlet 152 and the exhaust gas outlet 154 to each other to form an exhaust gas reaction space 157 therein. The reactive species supplied from the plasma reactor (110 of FIG. 1) and the ingredients to be treated included in the exhaust gas discharged from the semiconductor process chamber (102 of FIG. 1) are mixed with each other and react with each other in the exhaust gas reaction space 157. The exhaust gas reaction unit 156 has a cylindrical shape with the exhaust gas inlet 152 and the exhaust gas outlet 154 coaxially, and the exhaust gas reaction space 157 formed inside the exhaust gas reaction unit 156 has a cylindrical shape corresponding to an external shape of the exhaust gas reaction unit 156. The exhaust gas reaction space 157 generally has a disc shape with a low height and has a greater diameter than a diameter of the chamber exhaust pipe (107 of FIG. 1). Thus, the exhaust gas reaction space 157 has a size that is more enlarged outwards than the chamber exhaust pipe (107 of FIG. 1). The exhaust gas reaction space 157 communicates with the chamber exhaust pipe (107 of FIG. 1) through the exhaust gas inlet 152 and the exhaust gas outlet 154. The plasma inlet 158 connected to the plasma supply pipe 170 is formed on the outer circumference of the exhaust gas reaction unit 156. The reactive species generated by the plasma reactor (110 of FIG. 1) flows into the exhaust gas reaction space 157 through the plasma inlet 158.

The cooling unit 160 is installed on the exhaust gas reaction unit 156 of the chamber body 151, reduces the temperature of the exhaust gas reaction chamber 150 using a cooling water, thereby preventing damage of equipment due to overheat. The cooling unit 160 includes three cooling jackets 161, 163, and 165, and four cooling fluid pipes 166, 167, 168, and 169 connected to the three cooling jackets 161, 163, and 165.

One cooling jacket 161 of the three cooling jackets 161, 163, and 165 is an outer circumferential cooling jacket that surrounds an outer circumferential surface of the exhaust gas reaction unit 156, another one cooling jacket 163 thereof is an upstream-side end cooling jacket installed outside an end of an upstream of the exhaust gas reaction unit 156, and the other one cooling jacket 165 thereof is a downstream-side end cooling jacket installed outside an end of a downstream of the exhaust gas reaction unit 156. An outer circumferential cooling fluid accommodation space 161a in which a cooling fluid such as a cooling water is accommodated, is formed in the outer circumferential cooling jacket 161. An upstream-side cooling fluid accommodation space 163a in which the cooling fluid such as a cooling water is accommodated, is formed inside the upstream-side end cooling jacket 163. A downstream-side cooling fluid accommodation space 165a in which the cooling fluid such as a cooling water is accommodated, is formed inside the downstream-side end cooling jacket 165. The exhaust gas reaction unit 156 is cooled by the cooling fluid accommodated in each of the cooling fluid accommodation spaces 161a, 163a, and 165a of each of the three cooling jackets 161, 163, and 165. Four cooling fluid pipes 166, 167, 168, and 169 communicate with the three cooling jackets 161, 163, and 165. In the present embodiment, it has been described that there are three cooling jackets, but the present invention is not limited thereto. The number of cooling jackets may be two or less or four or more, and this also belongs to the scope of the present invention.

Four cooling fluid pipes 166, 167, 168, and 169 communicate with three cooling jackets 161, 163, and 165. One cooling fluid pipe 166 of the four cooling fluid pipes 166, 167, 168, and 169 is a first cooling fluid inlet pipe that communicates with the upstream-side end cooling jacket 163, another one cooling fluid pipe 167 thereof is a second cooling fluid inlet pipe that communicates with the downstream-side end cooling jacket 165, another one cooling fluid pipe 168 thereof is a first connection pipe that allows the upstream-side end cooling jacket 163 and the outer circumferential cooling jacket 161 to communicate with each other, and the other one cooling fluid pipe 169 thereof is a second connection pipe that allows the downstream-side end cooling jacket 165 and the outer circumferential cooling jacket 161 to communicate with each other. A cooling fluid C such as a cooling water flows into the upstream-side end cooling jacket 163 through the first cooling water inlet pipe 166, and the cooling fluid of the upstream-side end cooling jacket 163 flows into the outer circumferential cooling jacket 161 through the first connection pipe 168, and the cooling fluid of the outer circumferential cooling jacket 161 flows into the downstream-side end cooling jacket 165 through the second connection pipe 169, and the cooling water of the downstream-side end cooling jacket 165 is discharged through the second cooling water inlet pipe 167. In the present embodiment, it has been described that the cooling fluid flows through the first cooling water inlet pipe 166 and is discharged through the second cooling water inlet pipe 167, but this also belongs to the scope of the present invention.

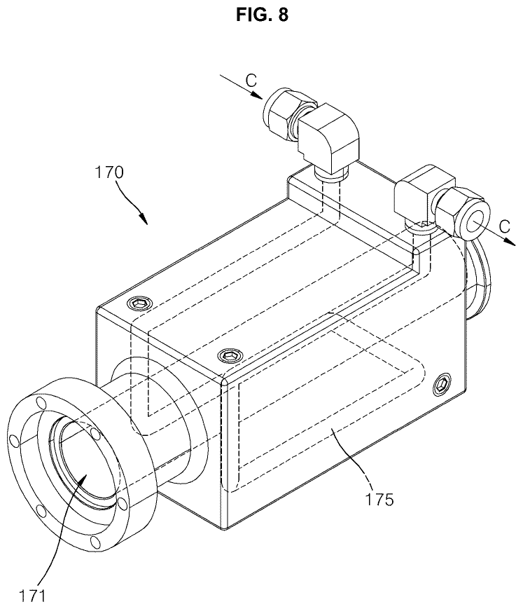

Referring to FIG. 2, the plasma supply pipe 170 connects the plasma reactor 110 and the plasma inlet 158 of the exhaust gas reaction chamber 150. The reactive species generated by the plasma reactor 110 are supplied to the exhaust gas reaction space 157 of the exhaust gas reaction chamber 150 through the plasma supply pipe 170. FIG. 8 shows the configuration of the plasma supply pipe 170. Referring to FIG. 8, a plasma supply passage 171 through which the plasma reactor 110 and the exhaust gas reaction chamber 150 communicate with each other, and a cooling fluid passage 175 formed to surround the plasma supply passage 171 from the outside are formed in the plasma supply pipe 170. The reactive species generated by the plasma reactor 110 flow into the exhaust gas reaction space 157 of the exhaust gas reaction chamber 150 through the plasma supply passage 171. The cooling fluid such as a cooling water flows through the cooling fluid passage 175, and the temperature of gas introduced into the exhaust gas reaction chamber 150 through the plasma supply passage 171 is reduced so that the cooling performance in the exhaust gas reaction chamber 150 may be enhanced.

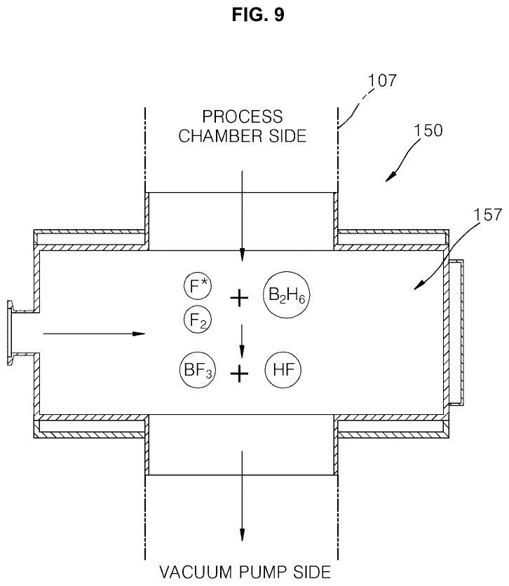

FIG. 9 illustrates a state in which pretreatment on an exhaust gas including B₂H₆ generated by a LFW process is performed in the exhaust gas reaction chamber 150. Referring to FIG. 9, in the exhaust gas reaction chamber 150, B₂H₆ contained in the exhaust gas reacts with excited fluorine atoms (F*) and fluorine (F₂), which are reactive species generated in the process of decomposing nitrogen trifluoride (NF₃) into plasma, B₂H₆ is removed by producing boron trifluoride (BF₃) and hydrofluoric acid (HF). By removing B₂H₆, generation of a membranous Wx by-product is prevented. Although not shown, the reactive active species (F*) discharged without reacting in the exhaust gas reaction chamber 150 flow into the vacuum pump (106 of FIG. 1), react with tungsten deposited on the vacuum pump (106 of FIG. 1), generates a tungsten hexafluoride (WF₆) gas so that tungsten deposited on the vacuum pump (106 of FIG. 1) may also be removed. In addition, although not shown, fluorine (F₂) discharged without reacting in the exhaust gas reaction chamber 150 flows into the vacuum pump (106 of FIG. 1), and reacts with hydrocarbons (C_{X}H_{Y}) deposited on the vacuum pump (106 of FIG. 1), generates carbon tetrafluoride (CF4) and hydrofluoric acid (HF) so that C_{X}H_{Y} deposited on the vacuum pump (106 of FIG. 1) may also be removed.

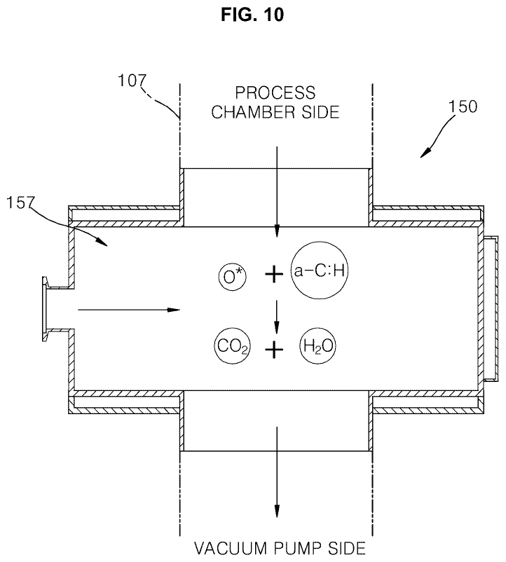

FIG. 10 illustrates a state in which pretreatment on an exhaust gas including a-C:H generated by an ACL process is performed in the exhaust gas reaction chamber 150. Referring to FIG. 10, in the exhaust gas reaction chamber 150, a-C:H contained in the exhaust gas reacts with excited oxygen atoms (O*), which are reactive species generated in the process of decomposing oxygen (O₂) into plasma, a-C:H is removed by producing carbon dioxide (CO₂) gas and water vapor (H₂O). Although not shown, the reactive active species (O*) discharged without reacting in the exhaust gas reaction chamber 150 flow into the vacuum pump (106 of FIG. 1), react with a-C:H deposited on the vacuum pump (106 of FIG. 1), generates a CO₂ gas and H₂O so that a-C:H deposited on the vacuum pump (106 of FIG. 1) may also be removed.

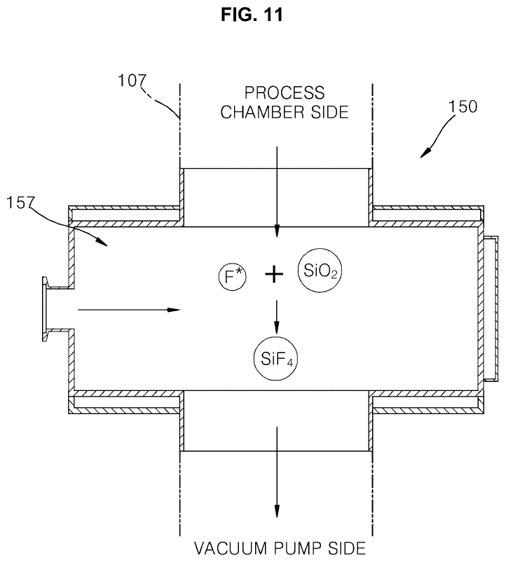

FIG. 11 illustrates a state in which pretreatment on an exhaust gas including a SiO₂ power generated by a TEOS process is performed in the exhaust gas reaction chamber 150. Referring to FIG. 11, in the exhaust gas reaction chamber 150, the SiO₂ powder contained in the exhaust gas reacts with excited fluorine atoms (F*), which are reactive species generated in the process of decomposing nitrogen trifluoride (NF₃) into plasma, the SiO₂ powder is removed by producing a silicon tetrafluoride (SiF₄) gas. By removing the SiO₂ powder, deposition of the SiO₂ powder on the vacuum pump (106 of FIG. 1) is prevented. Although not shown, the reactive active species (F*) discharged without reacting in the exhaust gas reaction chamber 150 flow into the vacuum pump (106 of FIG. 1), react with the SiO₂ powder deposited on the vacuum pump (106 of FIG. 1), generates a SiF₄ gas so that the SiO₂ powder deposited on the vacuum pump (106 of FIG. 1) may also be removed.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. Exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment comprising:
an exhaust gas reaction chamber installed on the chamber exhaust pipe; and
a plasma reactor generating a plasma gas including reactive species generated by decomposing a source gas by generating plasma,
wherein the exhaust gas reaction chamber comprises an exhaust gas reaction unit having an exhaust gas reaction space in which ingredients to be treated included in the exhaust gas and the reactive species are mixed with each other and react with each other, therein, and a cooling unit installed on the exhaust gas reaction unit.

2. The exhaust gas pretreatment equipment of claim 1, wherein the cooling unit comprises a cooling jacket installed outside the exhaust gas reaction unit and having a cooling fluid accommodation space in which a cooling fluid is accommodated, therein.

3. The exhaust gas pretreatment equipment of claim 2, wherein the cooling jacket is in plural, and the cooling unit further comprises a cooling fluid pipe connecting the plurality of cooling jackets to each other.

4. The exhaust gas pretreatment equipment of claim 1, wherein the exhaust gas reaction unit has a pillar shape that is more enlarged outwards than the chamber exhaust pipe.

5. The exhaust gas pretreatment equipment of claim 4, wherein the cooling unit comprises an outer circumferential cooling jacket installed to surround an outer circumferential surface of the exhaust gas reaction unit and having an outer circumferential cooling fluid accommodation space in which a cooling fluid is accommodated, therein.

6. The exhaust gas pretreatment equipment of claim 5, wherein the cooling unit further comprises an upstream-side end cooling jacket installed on an end of upstream of the exhaust gas reaction unit and having an upstream-side cooling fluid accommodation space in which a cooling fluid is accommodated, therein, and a downstream-side end cooling jacket installed on an end of downstream of the exhaust gas reaction unit and having a downstream-side cooling fluid accommodation space in which a cooling fluid is accommodated, therein.

7. The exhaust gas pretreatment equipment of claim 6, wherein the cooling unit further comprises a first connection pipe that allows the upstream-side end cooling jacket and the outer circumferential cooling jacket to communicate with each other, and a second connection pipe that allows the downstream-side end cooling jacket and the outer circumferential cooling jacket to communicate with each other.

8. The exhaust gas pretreatment equipment of claim 7, wherein the cooling unit further comprises a first cooling fluid inlet pipe that communicates with the upstream-side end cooling jacket, and a second cooling fluid inlet pipe that communicates with the downstream-side end cooling jacket.

9. The exhaust gas pretreatment equipment of claim 1, further comprising a plasma supply pipe connecting the exhaust gas reaction chamber and the plasma reactor to each other, wherein the plasma supply pipe comprises a plasma supply passage through which the plasma gas generated by the plasma reactor is discharged and flows, and a cooling fluid passage on which a cooling fluid flows.

10. Exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment comprising:
an exhaust gas reaction chamber installed on the chamber exhaust pipe;
a plasma reactor generating a plasma gas including reactive species generated by decomposing a source gas by generating plasma; and
a plasma supply pipe connecting the exhaust gas reaction chamber and the plasma reactor to each other,
wherein the plasma supply pipe comprises a plasma supply passage on which the plasma gas generated by the plasma reactor is discharged and flows, and a cooling fluid passage on which a cooling fluid flows, and
the exhaust gas reaction chamber comprises an exhaust gas reaction unit having an exhaust gas reaction space in which ingredients to be treated included in the exhaust gas and the reactive species introduced through the plasma supply passage are mixed with each other and react with each other, therein.

11. The exhaust gas pretreatment equipment of claim 1, wherein the source gas is nitrogen trifluoride (NF₃), and the reactive species comprise excited fluorine atoms (F*).

12. The exhaust gas pretreatment equipment of claim 11, wherein the exhaust gas comprises diborane (B₂H₆), and the diborane (B₂H₆) reacts with the excited fluorine atoms (F*) and is removed.

13. The exhaust gas pretreatment equipment of claim 11, wherein tungsten deposited on the vacuum pump reacts with excited fluorine atoms (F*) and is removed.

14. The exhaust gas pretreatment equipment of claim 11, wherein the exhaust gas comprises a silicon dioxide (SiO₂) powder, and the SiO₂ powder reacts with the excited fluorine atoms (F*) and is removed.

15. The exhaust gas pretreatment equipment of claim 1, wherein the source gas is oxygen (O₂), and the reactive species comprise excited oxygen atoms (O*).

16. The exhaust gas pretreatment equipment of claim 15, wherein the exhaust gas comprises hydrogenated amorphous carbon (a-C:H), and the a-C:H reacts with the excited oxygen atoms (O*) and is removed.

17. The exhaust gas pretreatment equipment of claim 10, wherein the source gas is nitrogen trifluoride (NF₃), and the reactive species comprise excited fluorine atoms (F*).

18. The exhaust gas pretreatment equipment of claim 10, wherein the source gas is oxygen (O₂), and the reactive species comprise excited oxygen atoms (O*).
